(19) United States
(12) Patent Application Publication
(10) Pub. No.: US 2023/0343701 A1
(43) Pub. Date: Oct. 26, 2023

(54) SEMICONDUCTOR DEVICE

(71) Applicant: RENESAS ELECTRONICS CORPORATION, Tokyo (JP)

(72) Inventors: Nobuhito SHIRAISHI, Tokyo (JP); Naohito SUZUMURA, Tokyo (JP)

(21) Appl. No.: 18/174,932

(22) Filed: Feb. 27, 2023

(30) Foreign Application Priority Data
Apr. 21, 2022 (JP) 2022-069989

(51) Int. Cl. H01L 23/522; H01C 7/00; H01L 23/532; H01L 21/768; H01C 17/12

(52) U.S. Cl. CPC H01L 23/5228; H01C 7/006; H01L 23/5226; H01L 23/53238; H01L 21/76832; H01L 28/24; H01C 17/12

(57) ABSTRACT

A semiconductor device includes first and second interlayer insulating films, first and second wirings, and a resistor film. The first wiring is disposed on the first interlayer insulating film. The second interlayer insulating film includes a first layer and a second layer. The first layer is disposed on the first interlayer insulating film so as to cover the first wiring. The resistor film is disposed on the first layer. The resistor film contains at least one selected from the group consisting of silicon chromium, silicon chromium into which carbon is introduced, nickel chromium, titanium nitride and tantalum nitride. The second layer is disposed on the first layer so as to cover the resistor film. The second wiring is disposed on the second layer. The resistor film is closer to the first wiring than to the second wiring in a thickness direction of the second interlayer insulating film.

### CROSS-REFERENCE TO RELATED APPLICATIONS

The disclosure of Japanese Patent Application No. 2022-069989 filed on Apr. 21, 2022 including the specification, drawings and abstract is incorporated herein by reference in its entirety.

### BACKGROUND

The present disclosure relates to a semiconductor device.

There is disclosed a technique listed below. [Patent Document 1] Japanese Unexamined Patent Application Publication No. 2011-155192

A semiconductor device described in Patent Document 1 includes a first interlayer insulating film and a second interlayer insulating film, a plurality of wiring layers, and a metal wiring layer. A first wiring is a wiring included in an uppermost wiring layer. The first wiring is disposed on the first interlayer insulating film. The second interlayer insulating film is disposed on the first interlayer insulating film so as to cover the first wiring. The metal wiring layer is disposed on the second interlayer insulating film, and is electrically connected to the first wiring. The metal wiring layer constitutes a resistor element.

### SUMMARY

In the semiconductor device described in Patent Document 1, a wiring included in a wiring layer other than the uppermost layer is defined as a second wiring, an interlayer insulating film that covers the second wiring is defined as a third interlayer insulating film, and a wiring disposed on the third interlayer insulating film is defined as a third wiring. In the case of intending to dispose the metal wiring layer on the third interlayer insulating film, the third interlayer insulating film is over-etched in the event of forming the third wiring, and in some cases, the metal wiring layer is exposed from the third interlayer insulating film.

When the metal wiring layer is formed of metal with a high melting point, such as chromium, the exposure of the metal wiring layer from the third interlayer insulating film spreads chromium to the periphery, so that reliability of a manufacturing process is lowered. Other objects and novel features will be apparent from the description in the specification and the accompanying drawings.

A semiconductor device according to the present disclosure includes a first interlayer insulating film, a second interlayer insulating film, a first wiring, a second wiring, and a resistor film. The first wiring is disposed on the first interlayer insulating film. The second interlayer insulating film includes a first layer and a second layer. The first layer is disposed on the first interlayer insulating film so as to cover the first wiring. The resistor film is disposed on the first layer. The resistor film contains at least one selected from the group consisting of silicon chromium, silicon chromium into which carbon is introduced, nickel chromium, titanium nitride and tantalum nitride. The second layer is disposed on the first layer so as to cover the resistor film. The second wiring is disposed on the second layer. The resistor film is closer to the first wiring than to the second wiring in a thickness direction of the second interlayer insulating film.

In accordance with the semiconductor device of the present disclosure, it is possible to ensure the reliability of the manufacturing process.

### BRIEF DESCRIPTION OF THE DRAWINGS

FIG. 1 is a cross-sectional view of a semiconductor device DEV1.

FIG. 2 is a manufacturing process chart of the semiconductor device DEV1.

FIG. 3 is a cross-sectional view for explaining a first wiring forming step S1.

FIG. 4 is a cross-sectional view for explaining a first interlayer insulating film forming step S2.

FIG. 5 is a cross-sectional view for explaining a via hole forming step S3.

FIG. 6 is a cross-sectional view for explaining a via plug forming step S4.

FIG. 7 is a cross-sectional view for explaining a resistor film forming step S5.

FIG. 8 is a cross-sectional view for explaining a second interlayer insulating film forming step S6.

FIG. 9 is a cross-sectional view for explaining a second wiring forming step S7.

FIG. 10 is a cross-sectional view of a semiconductor device DEV2.

FIG. 11 is a cross-sectional view of a semiconductor device DEV3.

FIG. 12 is a manufacturing process chart of the semiconductor device DEV3.

FIG. 13 is a cross-sectional view for explaining a resistor film forming step S9.

FIG. 14 is a cross-sectional view of a semiconductor device DEV4.

FIG. 15 is a manufacturing process chart of the semiconductor device DEV4.

FIG. 16 is a cross-sectional view for explaining a first wiring forming step S10.

FIG. 17 is a cross-sectional view for explaining a second wiring forming step S11.

FIG. 18 is a cross-sectional view of a semiconductor device DEV5.

FIG. 19 is a manufacturing process chart of the semiconductor device DEV5.

### DETAILED DESCRIPTION

Details of embodiments of the present disclosure will be described with reference to the drawings. In the following drawings, the same reference numerals are assigned to the same or corresponding portions, and a duplicate description thereof will not be repeated.

### First Embodiment

A semiconductor device according to a first embodiment will be described. The semiconductor device according to the first embodiment is defined as a semiconductor device DEV1.

Configuration of Semiconductor Device DEV1

A configuration of a semiconductor device DEV1 will be described below.

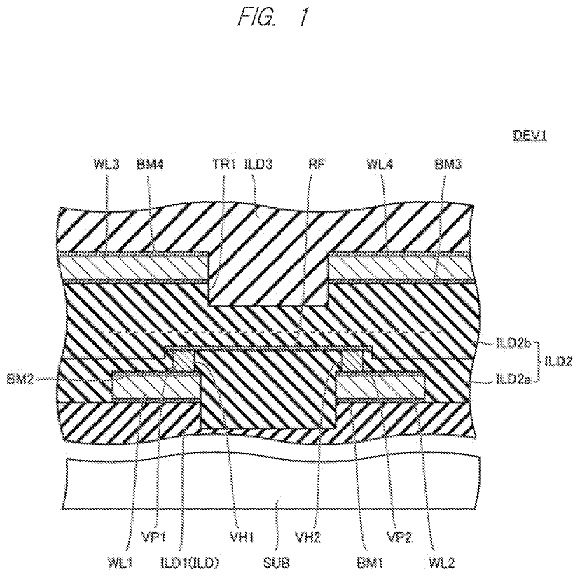

FIG. 1 is a cross-sectional view of the semiconductor device DEV1. As shown in FIG. 1, the semiconductor device DEV1 includes a semiconductor substrate SUB and a plurality of interlayer insulating films ILD. The plurality of interlayer insulating films ILD are disposed on the semiconductor substrate SUB. The semiconductor substrate SUB is formed, for example, of single crystal silicon (Si). The interlayer insulating films ILD are formed, for example, of silicon oxide (SiO₂). One of the plurality of interlayer insulating films ILD is defined as an interlayer insulating film ILD1.

The semiconductor device DEV1 includes a wiring WL1 and a wiring WL2. The wiring WL1 and the wiring WL2 are disposed on the interlayer insulating film ILD1. The wiring WL2 is arranged with the wiring WL1 at an interval. A barrier metal BM1 is disposed between the wiring WL1 and the interlayer insulating film ILD1 and between the wiring WL2 and the interlayer insulating film ILD1. A barrier metal BM2 is disposed on the wiring WL1 and the wiring WL2. The wiring WL1 and the wiring WL2 are formed of aluminum (Al) or an aluminum alloy. That is, the wiring WL1 and the wiring WL2 are aluminum wirings. Each of the barrier metal BM1 and the barrier metal BM2 is formed of a laminated film of a titanium nitride (TiN) film and a titanium (Ti) film.

Another one of the plurality of interlayer insulating films ILD is defined as an interlayer insulating film ILD2. The interlayer insulating film ILD2 includes a first layer ILD2a and a second layer ILD2b. The first layer ILD2a is disposed on the interlayer insulating film ILD1 so as to cover the wiring WL1, the wiring WL2, the barrier metal BM1 and the barrier metal BM2. A via hole VH1 and a via hole VH2 are formed in the first layer ILD2a. The via hole VH1 and the via hole VH2 penetrate the first layer ILD2a along a thickness direction thereof. In a bottom of the via hole VH1 and a bottom of the via hole VH2, a part of the wiring WL1 and a part of the wiring WL2 are exposed, respectively. The “thickness direction” is defined as a direction perpendicular to an upper surface of the interlayer insulating film ILD1 and an upper surface of the interlayer insulating film ILD2.

The semiconductor device DEV1 includes a via plug VP1 and a via plug VP2. The via plug VP1 and the via plug VP2 are embedded in the via hole VH1 and the via hole VH2, respectively. A lower end of the via plug VP1 is electrically connected to the wiring WL1. A lower end of the via plug VP2 is electrically connected to the wiring WL2. The via plug VP1 and the via plug VP2 are formed, for example, of tungsten (W).

The semiconductor device DEV1 includes a resistor film RF. The resistor film RF contains at least one selected from the group consisting of silicon chromium (SiCr), silicon chromium into which carbon (C) is introduced, nickel chromium (NiCr), titanium nitride and tantalum nitride (TaN). The resistor film RF is disposed on the first layer ILD2a. The resistor film RF is electrically connected to an upper end of the via plug VP1 and an upper end of the via plug VP2. Thus, the resistor film RF is electrically connected to the wiring WL1 and the wiring WL2.

The second layer ILD2b is disposed on the first layer ILD2a so as to cover the resistor film RF. The semiconductor device DEV1 includes a wiring WL3 and a wiring WL4. The wiring WL3 and the wiring WL4 are disposed on the second layer ILD2b. A barrier metal BM3 is disposed between the wiring WL3 and the interlayer insulating film ILD2 and between the wiring WL4 and the interlayer insulating film ILD2. A barrier metal BM4 is disposed on the wiring WL1 and the wiring WL2.

The wiring WL3 and the wiring WL4 are formed of aluminum or an aluminum alloy. That is, the wiring WL3 and the wiring WL4 are aluminum wirings. Each of the barrier metal BM3 and the barrier metal BM4 is formed of a laminated film of a titanium nitride film and a titanium film.

The wiring WL4 is arranged with the wiring WL3 at an interval. That is, an upper surface of the second layer ILD2b is exposed from between the wiring WL3 and the wiring WL4. In the thickness direction of the interlayer insulating film ILD2, the resistor film RF is closer to the wiring WL1 (wiring WL2) than to the wiring WL3 (wiring WL4). That is, the resistor film RF is located closer to the wiring WL1 (wiring WL2) than the center (indicated by a dotted line in FIG. 1) of the interlayer insulating film ILD2 in the thickness direction. From another viewpoint, a distance between a lower surface of the resistor film RF and an upper surface of the barrier metal BM2 in the thickness direction of the interlayer insulating film ILD2 is smaller than a distance between an upper surface of the resistor film RF and a lower surface of the barrier metal BM3 in the thickness direction of the interlayer insulating film ILD2 or between the upper surface of the resistor film RF and an uppermost surface of the interlayer insulating film ILD2 therein. Herein, the center of the interlayer insulating film ILD2 in the thickness direction is defined as the center of the interlayer insulating film ILD2 between the uppermost surface of the interlayer insulating film ILD2 and the wiring WL1 (wiring WL2). That is, in the thickness direction, a distance between the center of the interlayer insulating film ILD2 and the uppermost surface of the interlayer insulating film ILD2 is equal to an interval between the center of the interlayer insulating film ILD2 and an upper surface of the wiring WL1 (wiring WL2).

A trench TR1 is formed on the upper surface of the second layer ILD2b, which is exposed from between the wiring WL3 and the wiring WL4. In plan view, the trench TR1 overlaps a part of the resistor film RF. Preferably, in the thickness direction of the interlayer insulating film ILD2, the resistor film RF is closer to the wiring WL1 (wiring WL2) than to a bottom of the trench TR1.

Another one of the plurality of interlayer insulating films ILD is defined as an interlayer insulating film ILD3. The interlayer insulating film ILD3 is disposed on the interlayer insulating film ILD2 so as to cover the wiring WL3 and the wiring WL4. Although not shown, a wiring is further disposed on the interlayer insulating film ILD3.

Manufacturing Method of Semiconductor Device DEV1

A manufacturing method of the semiconductor device DEV1 will be described below.

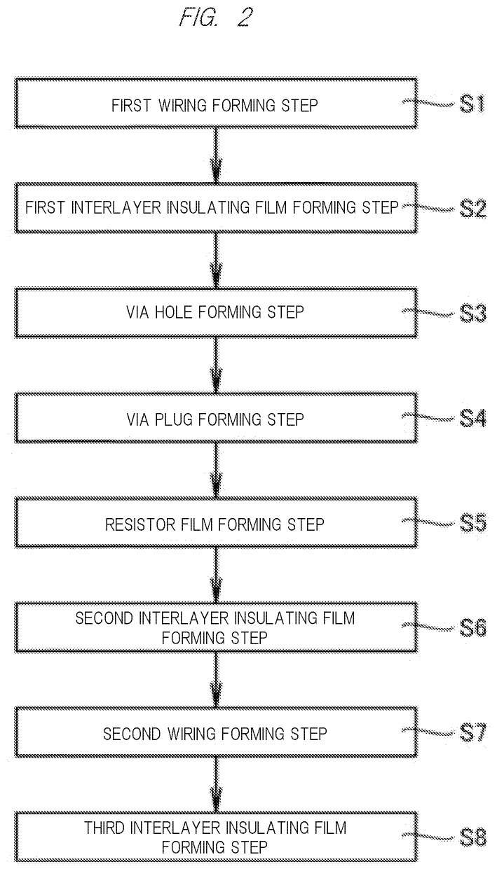

FIG. 2 is a manufacturing process chart of the semiconductor device DEV1. As shown in FIG. 2, the manufacturing method of the semiconductor device DEV1 includes a first wiring forming step S1, a first interlayer insulating film forming step S2, a via hole forming step S3, a via plug forming step S4, a resistor film forming step S5, a second interlayer insulating film forming step S6, a second wiring forming step S7, and a third interlayer insulating film forming step S8.

Before the first wiring forming step S1 is performed, the interlayer insulating film ILD1 and a structure located thereunder are formed. Since such structures just need to be formed by a well-known method, a description thereof will be omitted herein.

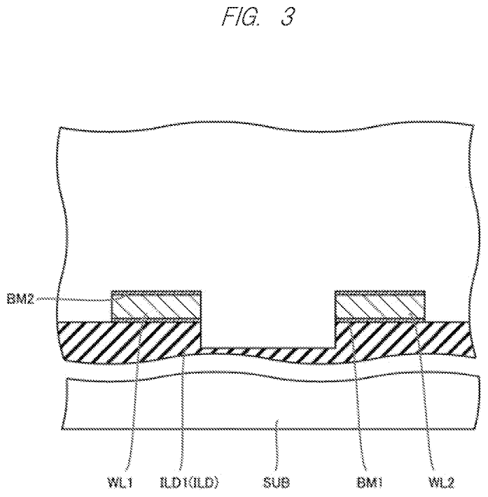

FIG. 3 is a cross-sectional view for explaining the first wiring forming step S1. As shown in FIG. 3, in the first wiring forming step S1, the wiring WL1, the wiring WL2, the barrier metal BM1 and the barrier metal BM2 are formed on the interlayer insulating film ILD1. In the first wiring forming step S1, first, constituent materials of the barrier metal BM1, the wiring WL1 (wiring WL2) and the barrier metal BM2 are sequentially deposited, for example, by a sputtering method. Second, a resist pattern is formed on the deposited constituent material of the barrier metal BM2. The resist pattern is formed by exposing and developing photoresist.

Third, by using the above-described resist pattern as a mask, the deposited constituent materials of the barrier metal BM1, the wiring WL1 (wiring WL2) and the barrier metal BM2 are etched. Thus, the wiring WL1, the wiring WL2, the barrier metal BM1 and the barrier metal BM2 are formed. When residues of the barrier metal BM1, the wiring WL1 (wiring WL2) and the barrier metal BM2 are left on the interlayer insulating film ILD1 in the event of the above-described etching, the wiring WL1 and the wiring WL2 may be short-circuited through such residues in some cases. For sure isolation between the wiring WL1 and the wiring WL2, the interlayer insulating film ILD1 is over-etched. As a result, a trench is formed on an upper surface of the interlayer insulating film ILD1 exposed from between the wiring WL1 and the wiring WL2. Note that the above-described resist pattern is removed after the wiring WL1, the wiring WL2, the barrier metal BM1 and the barrier metal BM2 are formed.

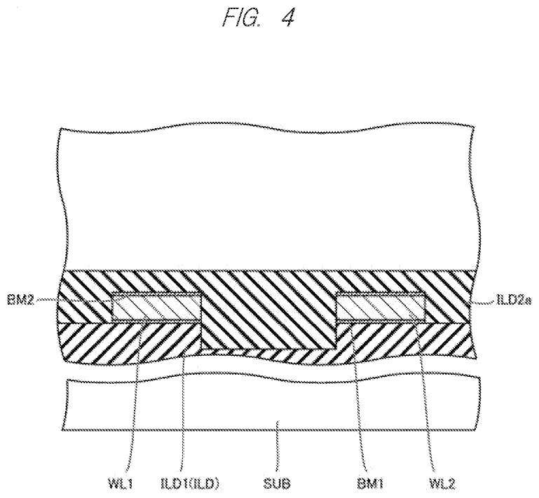

FIG. 4 is a cross-sectional view for explaining the first interlayer insulating film forming step S2. As shown in FIG. 4, in the first interlayer insulating film forming step S2, the first layer ILD2a is formed on the interlayer insulating film ILD1 so as to cover the wiring WL1, the wiring WL2, the barrier metal BM1 and the barrier metal BM2. In the first interlayer insulating film forming step S2, first, a constituent material of a first layer ILD2a is deposited on the interlayer insulating film ILD1, for example, by a chemical vapor deposition (CVD) method so as to cover the wiring WL1, the wiring WL2, the barrier metal BM1 and the barrier metal BM2. Second, the upper surface of the deposited constituent material of the first layer ILD2a is planarized, for example, by a chemical mechanical polishing (CMP) method. Thus, the first layer ILD2a is formed.

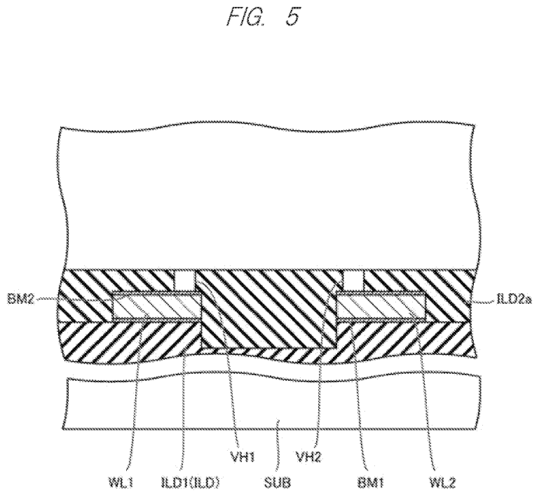

FIG. 5 is a cross-sectional view for explaining the via hole forming step S3. As shown in FIG. 5, in the via hole forming step S3, the via hole VH1 and the via hole VH2 are formed in the first layer ILD2a. In the via hole forming step S3, first, a resist pattern is formed on the first layer ILD2a. The resist pattern is formed by exposing and developing photoresist. Second, the first layer ILD2a is etched by using the above-described resist pattern as a mask. Thus, the via hole VH1 and the via hole VH2 are formed. Note that the above-described resist pattern is removed after the via hole VH1 and the via hole VH2 are formed.

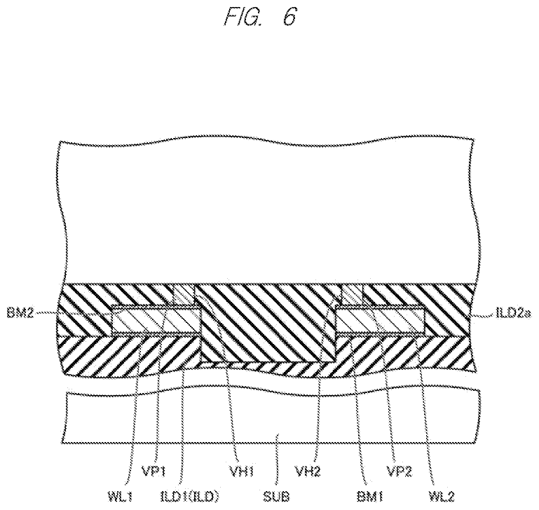

FIG. 6 is a cross-sectional view for explaining the via plug forming step S4. As shown in FIG. 6, in the via plug forming step S4, the via plug VP1 and the via plug VP2 are formed in the via hole VH1 and the via hole VH2. In the via plug forming step S4, first, for example, by the CVD method, the via hole VH1 and the via hole VH2 are embedded with a constituent material of the via plug VP1 (via plug VP2). Second, the constituent material of the via plug VP1 (via plug VP2), which has extended off from the via hole VH1 and the via hole VH2, is removed, for example, by the CMP method. Thus, the via plug VP1 and the via plug VP2 are formed.

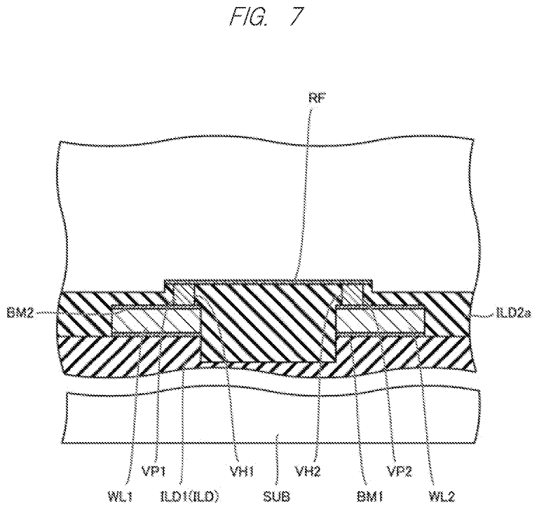

FIG. 7 is a cross-sectional view for explaining the resistor film forming step S5. As shown in FIG. 7, in the resistor film forming step S5, the resistor film RF is formed on the first layer ILD2a. In the resistor film forming step S5, first, a constituent material of the resistor film RF is formed on the first layer ILD2a, for example, by the sputtering method. Second, a resist pattern is formed on the deposited constituent material of the resistor film RF. The resist pattern is formed by exposing and developing photoresist. Second, the deposited constituent material of the resistor film RF is etched by using the above-described resist pattern as a mask. Thus, the resistor film RF is formed. Note that the above-described resist pattern is removed after the resistor film RF is formed.

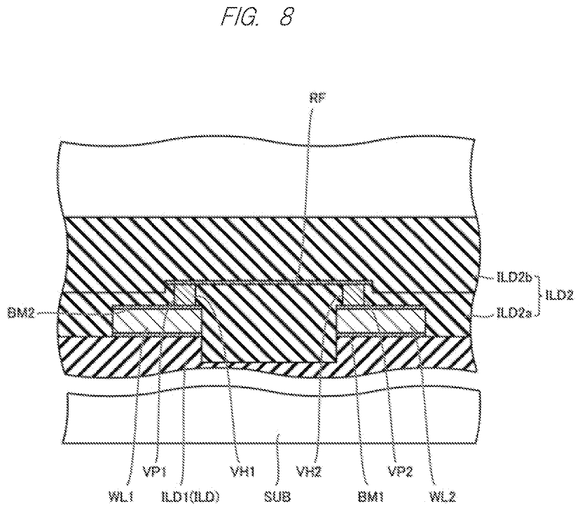

FIG. 8 is a cross-sectional view for explaining the second interlayer insulating film forming step S6. As shown in FIG. 8, in the second interlayer insulating film forming step S6, the second layer ILD2b is formed on the first layer ILD2a so as to cover the resistor film RF. In the second interlayer insulating film forming step S6, first, a constituent material of the second layer ILD2b is formed on the first layer ILD2a, for example, by the CVD method so as to cover the resistor film RF. Second, the upper surface of the deposited constituent material of the second layer ILD2b is planarized by, for example, the CMP method. Thus, the second layer ILD2b is formed.

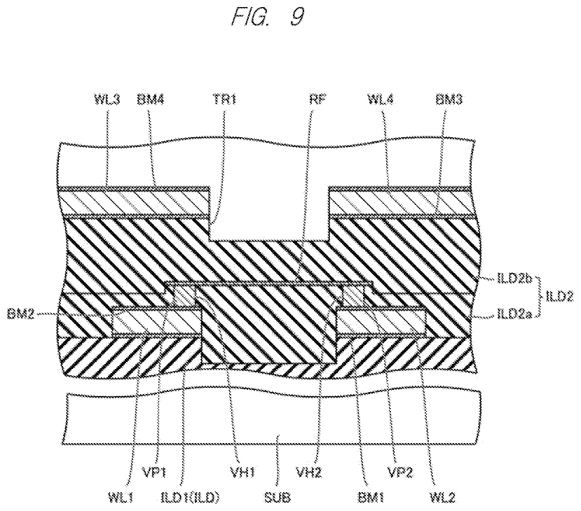

FIG. 9 is a cross-sectional view for explaining the second wiring forming step S7. As shown in FIG. 9, in the second wiring forming step S7, the wiring WL3, the wiring WL4, the barrier metal BM3 and the barrier metal BM4 are formed on the second layer ILD2b. In the second wiring forming step S7, first, constituent materials of the barrier metal BM3, the wiring WL3 (wiring WL4) and the barrier metal BM4 are sequentially deposited, for example, by the sputtering method. Second, a resist pattern is formed on the deposited constituent material of the barrier metal BM4. The resist pattern is formed by exposing and developing photoresist.

Third, by using the above-described resist pattern as a mask, the deposited constituent materials of the barrier metal BM3, the wiring WL3 (wiring WL4) and the barrier metal BM4 are etched. Thus, the wiring WL3, the wiring WL4, the barrier metal BM3 and the barrier metal BM4 are formed. When residues of the constituent material of the barrier metal BM3, the wiring WL3 (wiring WL4) and the barrier metal BM4 are left on the second layer ILD2b in the event of the above-described etching, the wiring WL3 and the wiring WL4 may be short-circuited through such residues in some cases. For sure isolation between the wiring WL3 and the wiring WL4, the second layer ILD2b is over-etched. As a result, the trench TR1 is formed on the upper surface of the second layer ILD2b, which is exposed from between the wiring WL3 and the wiring WL4. Note that the above-described resist pattern is removed after the wiring WL3, the wiring WL4, the barrier metal BM3 and the barrier metal BM4 are formed.

In the third interlayer insulating film forming step S8, the interlayer insulating film ILD3 is formed on the second layer ILD2b so as to cover the wiring WL3, the wiring WL4, the barrier metal BM3 and the barrier metal BM4. In the third interlayer insulating film forming step S8, first, a constituent material of the interlayer insulating film ILD3 is deposited on the second layer ILD2b, for example, by the CVD method so as to cover the wiring WL3, the wiring WL4, the barrier metal BM3 and the barrier metal BM4. Second, the upper surface of the deposited constituent material of the interlayer insulating film ILD3 is planarized by, for example, the CMP method. Thus, the semiconductor device DEV1 with a structure shown in FIG. 1 is formed.

Effects of Semiconductor Device DEV1

Effects of the semiconductor device DEV1 will be described while being compared with those of a semiconductor device according to a comparative example. The semiconductor device according to the comparative example is defined as a semiconductor device DEV2.

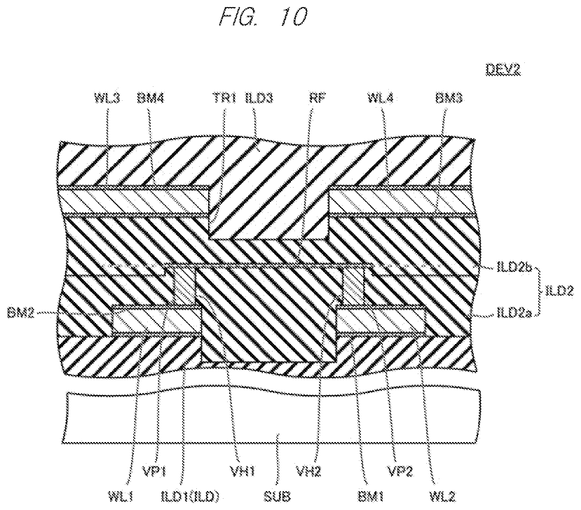

FIG. 10 is a cross-sectional view of the semiconductor device DEV2. As shown in FIG. 10, in the semiconductor device DEV2, the resistor film RF is located near the center (indicated by a dotted line in FIG. 10) in the thickness direction of the interlayer insulating film ILD2. That is, in the semiconductor device DEV2, the distance between the resistor film RF and the uppermost surface of the interlayer insulating film ILD2 is equal to the distance between the resistor film RF and the upper surface (upper surface of the wiring WL2) of the wiring WL1. With regard to other points, a configuration of the semiconductor device DEV2 is common to the configuration of the semiconductor device DEV1.

In the semiconductor device DEV2, the resistor film RF is located near the center in the thickness direction of the interlayer insulating film ILD2, and accordingly, the distance between the trench TR1 and the resistor film RF in the thickness direction of the interlayer insulating film ILD2 is small. Therefore, in the semiconductor device DEV2, the resistor film RF may sometimes be exposed from the bottom of the trench TR1 due to over-etching when the second wiring forming step S7 is performed. When the resistor film RF is exposed from the bottom of the trench TR1 to plasma for use in the etching, the constituent material of the resistor film RF spreads to the periphery. As a result, in a manufacturing process of the semiconductor device DEV2, reliability of this manufacturing process may decrease. Moreover, when the resistor film RF is exposed from the bottom of the trench TR1 to plasma, it is apprehended that characteristics of the resistor film RF may vary to a great extent, more specifically, that a resistance value of the resistor film RF may increase.

In the semiconductor device DEV2, the wiring WL1 (wiring WL2) is required to be disposed so as to overlap the resistor film RF in plan view in order to suppress such a reliability decrease of the manufacturing process and such a characteristic variation of the resistor film RF; however, in that case, a degree of freedom in wiring layout on the second layer ILD2b is impaired.

Meanwhile, in the semiconductor device DEV1, the resistor film RF is located closer to the wiring WL1 (wiring WL2) than the center in the thickness direction of the interlayer insulating film ILD2, and accordingly, the distance between the trench TR1 and the resistor film RF in the thickness direction of the interlayer insulating film ILD2 is large. As a result, in the semiconductor device DEV1, the resistor film RF is less likely to be exposed from the bottom of the trench TR1 due to the over-etching when the second wiring forming step S7 is performed. Therefore, in accordance with the semiconductor device DEV1, without impairing the degree of freedom in wiring layout on the second layer ILD2b, it is possible to suppress the constituent material of the resistor film RF from spreading to the periphery, and in addition, it is possible to suppress the characteristic variation of the resistor film RF.

In the semiconductor device DEV1, the resistor film RF is located closer to the wiring WL1 (wiring WL2) than the center in the thickness direction of the interlayer insulating film ILD2, and as a result, the distance between the resistor film RF and the wiring WL1 (wiring WL2) in the thickness direction of the interlayer insulating film ILD2 is reduced. Accordingly, heat generated in the resistor film RF is likely to be dissipated through the wiring WL1 (wiring WL2). Heat dissipation of the resistor film RF is further improved when the resistor film RF is electrically connected to the wiring WL1 and the wiring WL2 by the via plug VP1 and the via plug VP2.

Moreover, when the resistor film RF is closer to the wiring WL1 (wiring WL2) than to the bottom of the trench TR1 in the thickness direction of the interlayer insulating film ILD2, the distance between the trench TR1 and the resistor film RF in the thickness direction of the interlayer insulating film ILD2 is further increased. Therefore, it is possible to further suppress the constituent material of the resistor film RF from spreading to the periphery, and in addition, it is possible to further suppress the characteristic variation of the resistor film RF. In this case, the distance between the resistor film RF and the wiring WL1 (wiring WL2) in the thickness direction of the interlayer insulating film ILD2 is further reduced, and therefore, it is also possible to further improve the heat dissipation of the resistor film RF.

### Second Embodiment

A semiconductor device according to a second embodiment will be described. The semiconductor device according to the second embodiment is defined as a semiconductor device DEV3. Herein, points different from those of the semiconductor device DEV1 will be mainly described, and a duplicate description will not be repeated.

Configuration of Semiconductor Device DEV3

A configuration of the semiconductor device DEV3 will be described below.

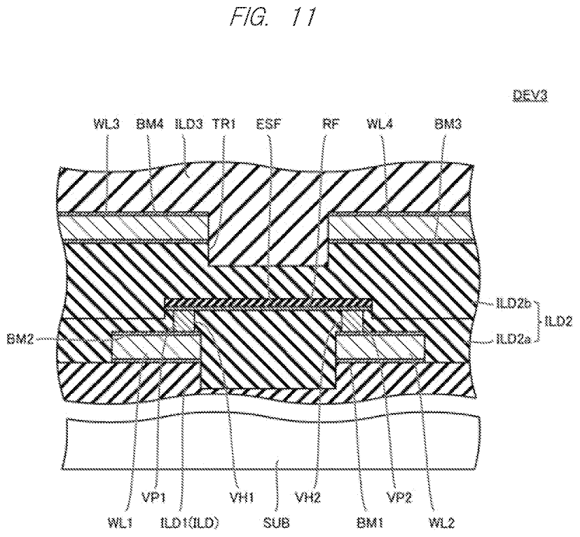

FIG. 11 is a cross-sectional view of the semiconductor device DEV3. As shown in FIG. 11, the semiconductor device DEV3 includes a semiconductor substrate SUB, an interlayer insulating film ILD1, an interlayer insulating film ILD2 and an interlayer insulating film ILD3, a wiring WL1, a wiring WL2, a wiring WL3 and a wiring WL4, a barrier metal BM1, a barrier metal BM2, a barrier metal BM3 and a barrier metal BM4, a resistor film RF, and a via plug VP1 and a via plug VP2.

In the semiconductor device DEV3, in the thickness direction of the interlayer insulating film ILD2, the resistor film RF is closer to the wiring WL1 (wiring WL2) than to the wiring WL3 (wiring WL4). In the semiconductor device DEV3, preferably, in the thickness direction of the interlayer insulating film ILD2, the resistor film RF is closer to the wiring WL1 (wiring WL2) than to a bottom of the trench TR1. With regard to these points, a configuration of the semiconductor device DEV3 is common to the configuration of the semiconductor device DEV1.

The semiconductor device DEV3 further includes an etching stopper film ESF. The etching stopper film ESF is formed of an insulating material. The etching stopper film ESF is formed, for example, of silicon oxynitride (SiON). The etching stopper film ESF is, for example, a mask (hard mask) for patterning the resistor film RF. A constituent material of the etching stopper film ESF is selected so that an etching rate of etching performed in a second wiring forming step S7 is smaller than that of a constituent material of the second layer ILD2b. In the semiconductor device DEV3, the second layer ILD2b is disposed on the interlayer insulating film ILD1 so as to cover the resistor film RF and the etching stopper film ESF. With regard to these points, a configuration of the semiconductor device DEV3 is different from the configuration of the semiconductor device DEV1.

Manufacturing Method of Semiconductor Device DEV3

A manufacturing method of the semiconductor device DEV3 will be described below.

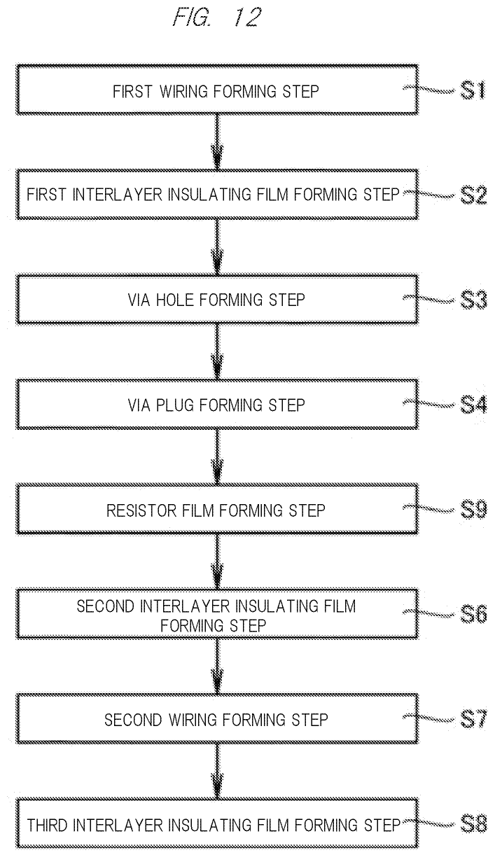

FIG. 12 is a manufacturing process chart of the semiconductor device DEV3. As shown in FIG. 12, the manufacturing method of the semiconductor device DEV3 includes a first wiring forming step S1, a first interlayer insulating film forming step S2, a via hole forming step S3, a via plug forming step S4, a resistor film forming step S9, a second interlayer insulating film forming step S6, a second wiring forming step S7, and a third interlayer insulating film forming step S8. That is, the manufacturing method of the semiconductor device DEV3 is different from the manufacturing method of the semiconductor device DEV1 in that the resistor film forming step S9 is provided in place of the resistor film forming step S5.

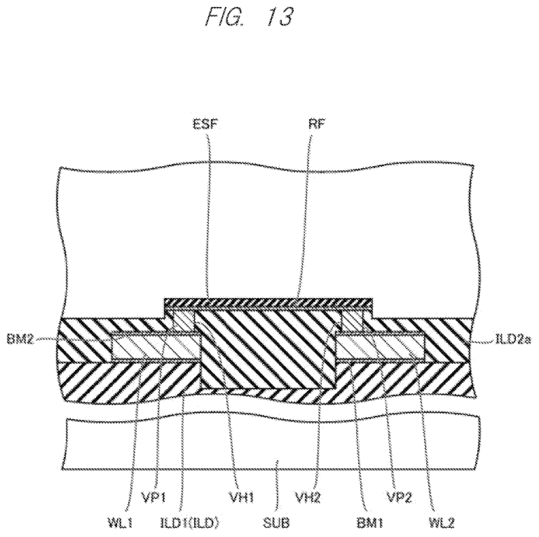

FIG. 13 is a cross-sectional view for explaining the resistor film forming step S9. As shown in FIG. 13, in the resistor film forming step S9, the resistor film RF is formed on the first layer ILD2a, and in addition, the etching stopper film ESF is formed on the resistor film RF. In the resistor film forming step S9, first, a constituent material of the resistor film RF and a constituent material of the etching stopper film ESF are sequentially deposited on the first layer ILD2a. Second, a resist pattern is formed on the deposited etching stopper film ESF. Third, the constituent material of the etching stopper film ESF is etched by using the above-described resist pattern as a mask. Thus, the etching stopper film ESF is formed. Note that the above-described resist pattern is removed after the etching stopper film ESF is formed.

Fourth, the deposited constituent material of the resistor film RF is etched by using the etching stopper film ESF as a mask. Note that the etching stopper film ESF is not removed after the resistor film RF is formed. Thus, the resistor film RF and the etching stopper film ESF are formed.

Effects of Semiconductor Device DEV3

Effects of the semiconductor device DEV3 will be described below.

In the semiconductor device DEV3, even if the etching stopper film ESF is exposed from the bottom of the trench TR1 due to the over-etching performed in the second wiring forming step S7, this over-etching is stopped by the etching stopper film ESF since the constituent material of the etching stopper film ESF and the constituent material of the interlayer insulating film ILD2 are different from each other. Therefore, in accordance with the semiconductor device DEV3, the exposure of the resistor film RF from the trench TR1, which may be caused by the over-etching when the second wiring forming step S7 is performed, is less likely to occur, and it is further possible to suppress the spreading of the constituent material of the resistor film RF to the periphery and the characteristic variation of the resistor film RF.

### Third Embodiment

A semiconductor device according to a third embodiment will be described. The semiconductor device according to the third embodiment is defined as a semiconductor device DEV4. Herein, points different from those of the semiconductor device DEV1 will be mainly described, and a duplicate description will not be repeated.

Configuration of Semiconductor Device DEV4

A configuration of the semiconductor device DEV4 will be described below.

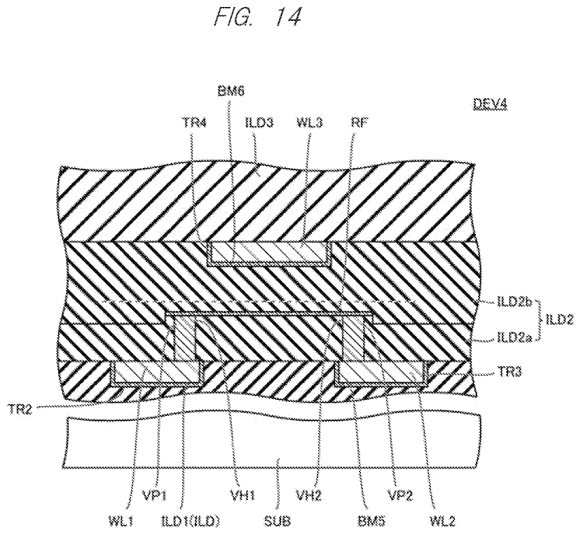

FIG. 14 is a cross-sectional view of the semiconductor device DEV4. As shown in FIG. 14, the semiconductor device DEV3 includes a semiconductor substrate SUB, an interlayer insulating film ILD1, an interlayer insulating film ILD2 and an interlayer insulating film ILD3, a wiring WL1, a wiring WL2, a wiring WL3, a resistor film RF, and a via plug VP1 and a via plug VP2. In the semiconductor device DEV4, the resistor film RF is located closer to the wiring WL1 (wiring WL2) than the center (indicated by a dotted line in FIG. 14) in the thickness direction of the interlayer insulating film ILD2. With regard to these points, a configuration of the semiconductor device DEV4 is common to the configuration of the semiconductor device DEV1.

In the semiconductor device DEV4, a wiring trench TR2 and a wiring trench TR3 are formed on an upper surface of the interlayer insulating film ILD1. In the semiconductor device DEV4, a wiring trench TR4 is formed on an upper surface of the second layer ILD2b. In the semiconductor device DEV4, the wiring WL1, the wiring WL2 and the wiring WL3 are embedded in the wiring trench TR2, the wiring trench TR3 and the wiring trench TR4, respectively. In the semiconductor device DEV4, the wiring WL1, the wiring WL2 and the wiring WL3 are copper (Cu) wirings. That is, in the semiconductor device DEV4, the wiring WL1, the wiring WL2 and the wiring WL3 are formed of copper or a copper alloy.

In the semiconductor device DEV4, the via plug VP1 and the via plug VP2 are embedded in the via hole VH1 and the via hole VH2, respectively. The via plug VP1 and the via plug VP2 are formed, for example, of tungsten or copper.

In the semiconductor device DEV4, the wiring trench TR4 overlaps at least a part of the resistor film RF in plan view. In the semiconductor device DEV4, in the thickness direction of the interlayer insulating film ILD2, the resistor film RF is closer to the wiring WL1 (wiring WL2) than to a bottom of the wiring trench TR4.

In the semiconductor device DEV4, barrier metals BM5 are disposed on the bottom surface and side surface of the wiring trench TR2 and on the bottom surface and side surface of the wiring trench TR3, and a barrier metal BM6 is disposed on the bottom surface and side surface of the wiring trench TR4. With regard to these points, a configuration of the semiconductor device DEV4 is different from the configuration of the semiconductor device DEV1.

Manufacturing Method of Semiconductor Device DEV4

A manufacturing method of the semiconductor device DEV4 will be described below.

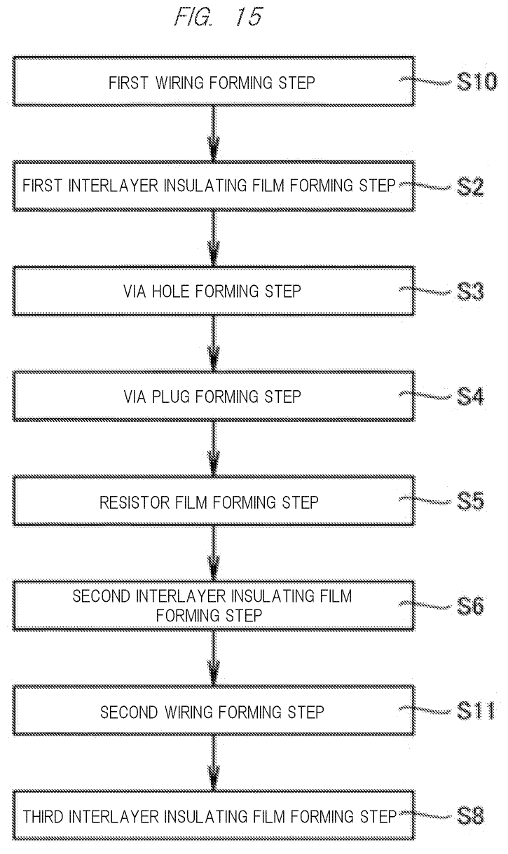

FIG. 15 is a manufacturing process chart of the semiconductor device DEV4. As shown in FIG. 15, the manufacturing method of the semiconductor device DEV4 includes a first wiring forming step S10 in place of the first wiring forming step S1, and includes a second wiring forming step S11 in place of the second wiring forming step S7. With regard to these points, the manufacturing method of the semiconductor device DEV4 is different from the manufacturing method of the semiconductor device DEV1.

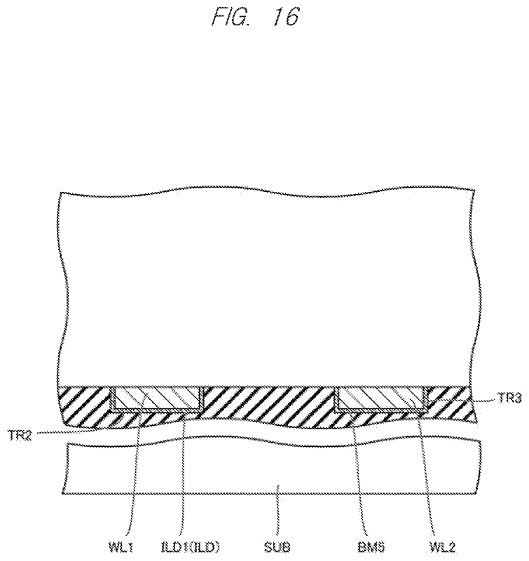

FIG. 16 is a cross-sectional view for explaining the first wiring forming step S10. In the first wiring forming step S10, as shown in FIG. 16, the wiring trench TR2, the wiring trench TR3, the barrier metal BM5, the wiring WL1 and the wiring WL2 are formed. In the first wiring forming step S10, the wiring trench TR2 and the wiring trench TR3 are formed on an upper surface of the interlayer insulating film ILD1. The wiring trench TR2 and the wiring trench TR3 are formed by etching the upper surface of the interlayer insulating film ILD1 by using, as a mask, a resist pattern disposed on the interlayer insulating film ILD1. Note that this resist pattern is removed after the wiring trench TR2 and the wiring trench TR3 are formed.

Second, a constituent material of the barrier metal BM5 is deposited on the interlayer insulating film ILD1 by the sputtering method and the like. Third, a seed layer is formed on the barrier metal BM5 by the sputtering method and the like. Fourth, the above-described seed layer is energized to perform electroplating, whereby the wiring trench TR2 and the wiring trench TR3 are embedded with the constituent material of the wiring WL1 (wiring WL2). Fifth, the constituent material of the barrier metal BM5 and the constituent material of the wiring WL1 (wiring WL2), which extend off from the wiring trench TR2 and the wiring trench TR3, are removed, for example, by the CMP method. Thus, the barrier metal BM5, the wiring WL1 and the wiring WL2 are formed.

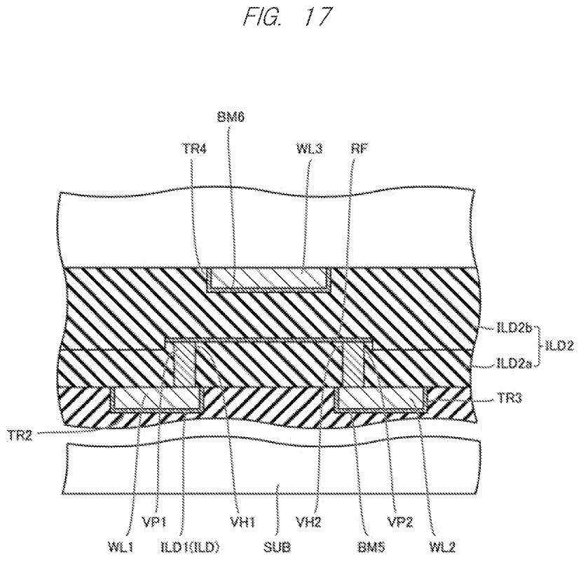

FIG. 17 is a cross-sectional view for explaining the second wiring forming step S11. In the second wiring forming step S11, as shown in FIG. 17, the wiring trench TR4, the barrier metal BM6 and the wiring WL3 are formed. In the second wiring forming step S11, first, the wiring trench TR4 is formed on the upper surface of the second layer ILD2b. The wiring trench TR4 is formed by etching the upper surface of the second layer ILD2b by using, as a mask, a resist pattern disposed on the second layer ILD2b. Note that this resist pattern is removed after the wiring trench TR4 is formed.

Second, a constituent material of the barrier metal BM6 is deposited on the second layer ILD2b by the sputtering method and the like. Fourth, a seed layer is formed on the barrier metal BM6 by the sputtering method and the like. Fourth, the above-described seed layer is energized to perform electroplating, whereby the wiring trench TR4 is embedded with the constituent material of the wiring WL3. Fifth, the constituent material of the barrier metal BM6 and the constituent material of the wiring WL3, which extend off from the wiring trench TR4, are removed, for example, by the CMP method. Thus, the barrier metal BM6 and the wiring WL3 are formed.

Effects of Semiconductor Device DEV4

Effects of the semiconductor device DEV4 will be described below.

In the semiconductor device DEV4, the resistor film RF is located closer to the wiring WL1 (wiring WL2) than the center in the thickness direction of the interlayer insulating film ILD2. Therefore, the resistor film RF is less likely to be exposed from the bottom of the wiring trench TR4 when the etching to form the wiring trench TR4 is performed in the second wiring forming step S11. Therefore, in accordance with the semiconductor device DEV4, it is possible to suppress the spreading of the constituent material of the resistor film RF to the periphery and the characteristic variation of the resistor film RF.

In the semiconductor device DEV4, the wiring WL1, the wiring WL2 and the wiring WL3 are copper wirings. Copper has higher thermal conductivity than aluminum. Therefore, in the semiconductor device DEV4, heat generated in the resistor film RF is likely to be dissipated through the wiring WL1 (wiring WL2) in comparison with the case where the wiring WL1, the wiring WL2 and the wiring WL3 are aluminum wirings. Heat dissipation of the resistor film RF is further improved when the resistor film RF is electrically connected to the wiring WL1 and the wiring WL2 by the via plug VP1 and the via plug VP2.

### Fourth Embodiment

A semiconductor device according to a fourth embodiment will be described. The semiconductor device according to the fourth embodiment is defined as a semiconductor device DEV5. Herein, points different from those of the semiconductor device DEV1 will be mainly described, and a duplicate description will not be repeated.

Configuration of Semiconductor Device DEV5

A configuration of the semiconductor device DEV5 will be described below.

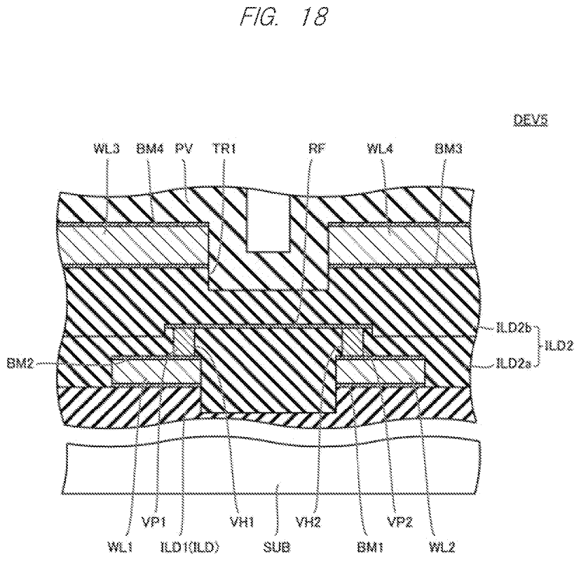

FIG. 18 is a cross-sectional view of the semiconductor device DEV5. As shown in FIG. 18, the semiconductor device DEV5 includes a semiconductor substrate SUB, an interlayer insulating film ILD1 and an interlayer insulating film ILD2, a wiring WL1, a wiring WL2, a wiring WL3 and a wiring WL4, a barrier metal BM1, a barrier metal BM2, a barrier metal BM3 and a barrier metal BM4, a resistor film RF, and a via plug VP1 and a via plug VP2.

In the semiconductor device DEV5, in the thickness direction of the interlayer insulating film ILD2, the resistor film RF is closer to the wiring WL1 (wiring WL2) than to the wiring WL3 (wiring WL4). In the semiconductor device DEV5, preferably, in the thickness direction of the interlayer insulating film ILD2, the resistor film RF is closer to the wiring WL1 (wiring WL2) than to a bottom of the trench TR1. With regard to these points, a configuration of the semiconductor device DEV5 is common to the configuration of the semiconductor device DEV1.

In the semiconductor device DEV5, the thickness of the wiring WL3 is larger than the thickness of the wiring WL1 and the thickness of the wiring WL2, and the thickness of the wiring WL4 is larger than the thickness of the wiring WL1 and the thickness of the wiring WL2. In the semiconductor device DEV5, the wiring WL1, the wiring WL2, the wiring WL3 and the wiring WL4 are, for example, global wirings. In the semiconductor device DEV5, the wiring WL3 and the wiring WL4 are, for example, uppermost wirings. Therefore, the semiconductor device DEV5 includes a passivation film PV in place of the interlayer insulating film ILD3. The passivation film PV is disposed on the second layer ILD2b so as to cover the wiring WL3 and the wiring WL4. The passivation film PV is formed, for example, of silicon nitride (SiN). With regard to these points, a configuration of the semiconductor device DEV5 is different from the configuration of the semiconductor device DEV1.

Manufacturing Method of Semiconductor Device DEV5

A manufacturing method of the semiconductor device DEV5 will be described below.

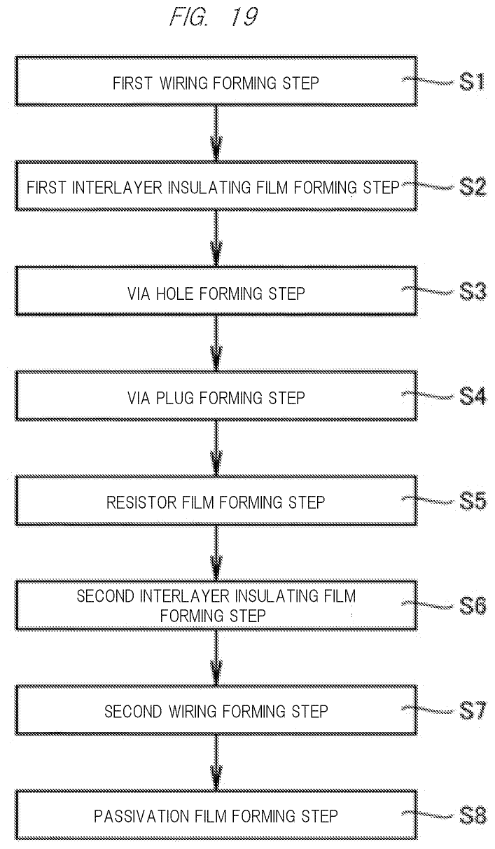

FIG. 19 is a manufacturing process chart of the semiconductor device DEV5. As shown in FIG. 19, the manufacturing method of the semiconductor device DEV5 includes a first wiring forming step S1, a first interlayer insulating film forming step S2, a via hole forming step S3, a via plug forming step S4, a resistor film forming step S5, a second interlayer insulating film forming step S6, a second wiring forming step S7, and a passivation film forming step S12. That is, the manufacturing method of the semiconductor device DEV5 is different from the manufacturing method of the semiconductor device DEV1 in that the passivation film forming step S12 is provided in place of the third interlayer insulating film forming step S8. Note that, in the passivation film forming step S12, the passivation film PV is formed on the second layer ILD2b by, for example, the CVD method so as to cover the wiring WL3 and the wiring WL4.

Effects of Semiconductor Device DEV5

Effects of the semiconductor device DEV5 will be described below.

When the thickness of the wiring WL3 and the wiring WL4 is increased, an over-etching amount in the second wiring forming step S7 is increased, and accordingly, the trench TR1 is deepened. That is, when the thickness of the wiring WL3 and the wiring WL4 is increased, the resistor film RF is likely to be exposed from the bottom of the trench TR1.

However, in the semiconductor device DEV5, the resistor film RF is closer to the wiring WL1 (wiring WL2) than to the wiring WL3 (wiring WL4) in the thickness direction of the interlayer insulating film ILD2, and accordingly, even if the trench TR1 is deepened, the resistor film RF is less likely to be exposed from the bottom of the trench TR1. As described above, in accordance with the semiconductor device DEV5, even if the wiring WL3 and the wiring WL4 are thickened more than the wiring WL1 (wiring WL2), it is possible to suppress the spreading of the constituent material of the resistor film RF to the periphery and the characteristic variation of the resistor film RF.

Note that, in the semiconductor device DEV5, the resistor film RF is disposed in a global wiring layer, so that the resistor film RF can be shared between a plurality of circuits included in the semiconductor device DEV5. Therefore, it becomes possible to reduce a chip area.

While the invention made by the inventor thereof has been specifically described on the basis of the embodiments thereof, needless to say, the present invention is not limited to the above-described embodiments, and is modifiable in various ways within the scope without departing from the spirit thereof.

What is claimed is:

1. A semiconductor device comprising:
a first interlayer insulating film;
a second interlayer insulating film;
a first wiring;
a second wiring; and
a resistor film,
wherein the first wiring is disposed on the first interlayer insulating film,
wherein the second interlayer insulating film includes a first layer and a second layer,
wherein the first layer is disposed on the first interlayer insulating film so as to cover the first wiring,
wherein the resistor film is disposed on the first layer,
wherein the resistor film contains at least one selected from the group consisting of silicon chromium, silicon chromium into which carbon is introduced, nickel chromium, titanium nitride and tantalum nitride,
wherein the second layer is disposed on the first layer so as to cover the resistor film,
wherein the second wiring is disposed on the second layer, and
wherein the resistor film is closer to the first wiring than to the second wiring in a thickness direction of the second interlayer insulating film.

2. The semiconductor device according to claim 1, comprising a third wiring disposed on the second layer,
wherein the third wiring is arranged adjacent to the second wiring,
wherein a gap is provided between the second wiring and the third wiring, and
wherein the gap overlaps at least a part of the resistor film in plan view.

3. The semiconductor device according to claim 1, comprising a third wiring disposed on the second layer,
wherein the third wiring is arranged adjacent to the second wiring,
wherein a gap is provided between the second wiring and the third wiring,
wherein a trench is formed on an upper surface of the second layer exposed from the gap,
wherein the gap overlaps at least a part of the resistor film in plan view, and
wherein the resistor film is closer to the first wiring than to a bottom of the trench in the thickness direction of the second interlayer insulating film.

4. The semiconductor device according to claim 1, comprising an etching stopper film formed of an insulator,
wherein the etching stopper film is disposed on the resistor film, and
wherein the second layer is disposed on the first layer so as to cover the resistor film and the etching stopper film.

5. The semiconductor device according to claim 4, wherein the insulator is formed of silicon oxynitride.

6. The semiconductor device according to claim 4, wherein the etching stopper film is a mask for patterning the resistor film.

7. The semiconductor device according to claim 1, wherein each of the first wiring and the second wiring is formed of aluminum or an aluminum alloy.

8. The semiconductor device according to claim 1,
wherein a first wiring trench is formed on an upper surface of the first interlayer insulating film,
wherein the first wiring is embedded in the first wiring trench,
wherein a second wiring trench is formed on an upper surface of the second layer,
wherein the second wiring is embedded in the second wiring trench, and
wherein each of the first wiring and the second wiring is formed of copper or a copper alloy.

9. The semiconductor device according to claim 8, wherein the resistor film is closer to the first wiring than to the second wiring trench in the thickness direction of the second interlayer insulating film.

10. The semiconductor device according to claim 1, wherein a thickness of the second wiring is larger than a thickness of the first wiring.

11. The semiconductor device according to claim 1, comprising a via plug,
wherein a via hole is formed in the first layer, the via hole penetrating the first layer along the thickness direction, and exposing a part of the first wiring, and
wherein the via plug is embedded in the via hole, and electrically connects the resistor film and the first wiring to each other.
